(19) United States
(12) Patent Application Publication
(10) Pub. No.: US 2007/0072090 A1
(43) Pub. Date: Mar. 29, 2007

(54) RETICLE HAVING A PROTECTION LAYER

(76) Inventors: Sheng-Yueh Chang, Taipei Hsien (TW); Te-Hung Wu, Tainan Hsien (TW); Kuo-Chun Huang, Tai-Nan City (TW)

Correspondence Address: NORTH AMERICA INTELLECTUAL PROPERTY CORPORATION, P.O. BOX 506, MERRIFIELD, VA, 22116, US

(21) Appl. No.: 11/162,913

(22) Filed: Sep. 28, 2005

(51) Int. Cl. G03F 1/14; A47G 1/12; G03F 1/00

(52) U.S. Cl. 430/5; 428/14

(57) ABSTRACT

A reticle includes a reticle body having a first surface, a pattern disposed on the first surface of the reticle body, and at least a protection layer disposed on the first surface of the reticle body. The protection layer is in contact with the first surface of the reticle body.

### BACKGROUND OF THE INVENTION

1. Field of the Invention

The present invention relates to a reticle having a protection layer thereon, and more particularly, to a reticle that has a passivation layer disposed thereon to isolate the pattern of the reticle from the environment.

2. Description of the Prior Art

In a photolithography process, a reticle (photomask) plays an important role. The reticle, like a mold in a printing process, has a predetermined pattern thereon, and the pattern can be transferred to a photoresist layer by an exposure process. Therefore, the pattern of the reticle is critical to the accuracy of pattern transfer. If particles (referred to as the haze defect) appear in the reticle, the transferred pattern will be influenced.

Please refer to FIG. 1 and FIG. 2. FIG. 1 illustrates a schematic view of a conventional reticle 10, and FIG. 2 illustrates the conventional reticle 10 during an exposure process. As shown in FIG. 1 and FIG. 2, the conventional reticle 10 includes a reticle body 12, a pattern 14 disposed on the surface of the reticle body 12, a frame 16 disposed in the reticle body 12, and a pellicle 18 mounted on the frame 16. The reticle body 12 is made of transparent materials, e.g. glass or quartz, and the pattern 14 is made of opaque materials, e.g. chromium, to shield the exposure light. In the exposure process, the exposure light, which is not shielded by the pattern 14, passes through to a lens 30 to be focused on a wafer 40. Consequently, the pattern 14 disposed on the reticle body 12 can be transferred to the wafer 40. The pellicle 18 is mounted on the reticle body 12 with the frame 16, and the purpose of the pellicle 18 is to keep away particles that may influence the accuracy of pattern transfer. As shown in FIG. 2, unexpected external particles 20 may appear during the exposure process. With the pellicle 18, the particles 20 do not influence the accuracy of pattern transfer since the exposure light shielded by the particles adhered to the pellicle 18 does not focus on the wafer.

The pellicle 18 may be able to ensure the accuracy of pattern transfer if the particles 20 appear on the surface of the pellicle 18. However, since the pellicle 18 does not completely surround the pattern 14, particles 20 may still appear on the surface of the reticle body 12 and the pattern 14. This is commonly referred to as the haze defect. Please refer to FIG. 3. FIG. 3 illustrates a schematic view of the reticle 10 when particles 20 appear on the reticle body 12. As shown in FIG. 3, the reticle 10 needs to be cleaned regularly. The clean solution normally contains sulfuric acid, and the sulfuric acid may react with ammonia that commonly exists in the reaction chamber. Consequently, ammonium sulfate particles 20 will appear on the surface of the pattern 14 and the reticle body 12. When particles 20 exist on the surface of the reticle body 12, the accuracy of pattern transfer will be reduced.

### SUMMARY OF THE INVENTION

It is therefore one of the objectives of the claimed invention to reduce the haze defect in reticles.

According to the claimed invention, a reticle is disclosed. The reticle includes a reticle body having a first surface, a pattern disposed on the first surface of the reticle body, and at least a protection layer disposed on the first surface of the reticle body. The protection layer covers the first surface of the reticle body, and has high transparency and refraction rate for any wavelength of exposure light. The refraction rate of the protection layer should be higher than that of air.

Since the protection layer covers the surface of the reticle body, the haze defect due to particles adhered to the surface of the reticle body is reduced. In addition, the protection layer is also able to protect the pattern from being damaged by external forces.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a schematic view of a conventional reticle.

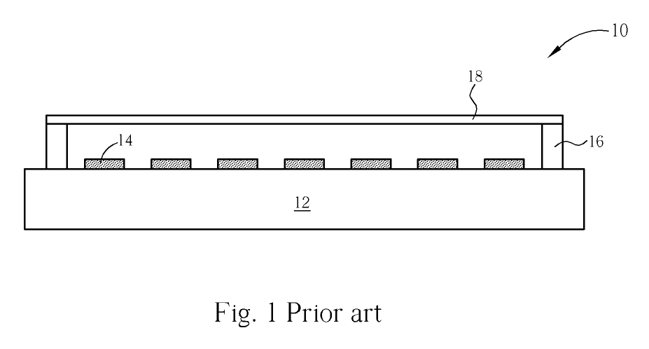

FIG. 2 illustrates the conventional reticle during an exposure process.

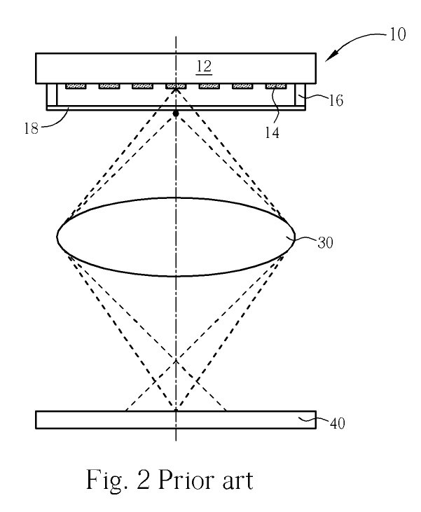

FIG. 3 illustrate a schematic view of the reticle when particles appear on the reticle body.

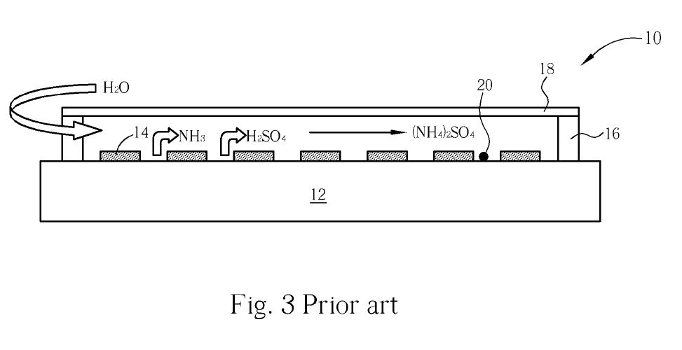

FIG. 4 illustrates a schematic view of a reticle according a first preferred embodiment of the present invention.

FIG. 5 illustrates the chemical structure of ring opening metathesis polymer (ROMP).

FIG. 6 illustrates a schematic view of a reticle according a second preferred embodiment of the present invention.

FIG. 7 illustrates a schematic view of a reticle according a third preferred embodiment of the present invention.

FIG. 8 illustrates a schematic view of a reticle according a fourth preferred embodiment of the present invention.

### DETAILED DESCRIPTION

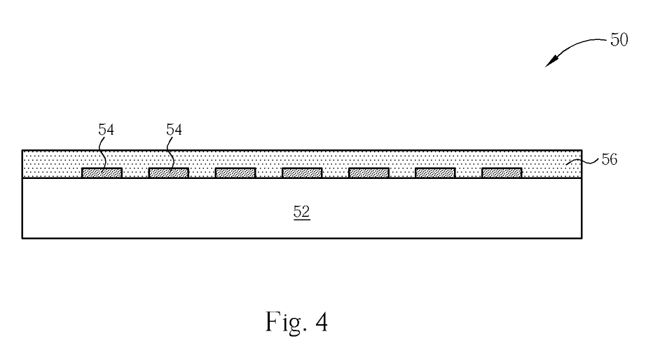

Please refer to FIG. 4. FIG. 4 illustrates a schematic view of a reticle 50 according a first preferred embodiment of the present invention. As shown in FIG. 4, the reticle 50 of the present invention includes a reticle body 52, a pattern 54 disposed on a first surface of the reticle body 52, and a protection layer 56 disposed on the first surface of the reticle body 52. The reticle body 52 is made of transparent materials, e.g. glass or quartz, and the pattern 54 is made of opaque materials, e.g. chromium, to shield the exposure light. The protection layer 56 disposed on the first surface of the reticle body 12 is to reduce the haze defect that influences the accuracy of pattern transfer. In this embodiment, since the protection layer 56 further covers the pattern 54, it also works to isolate the pattern 54 and the reticle body 52 so that the reticle 50 is well protected. By virtue of the protection layer 56, the pattern 54 can be correctly transferred to the photoresist layer disposed on the wafer.

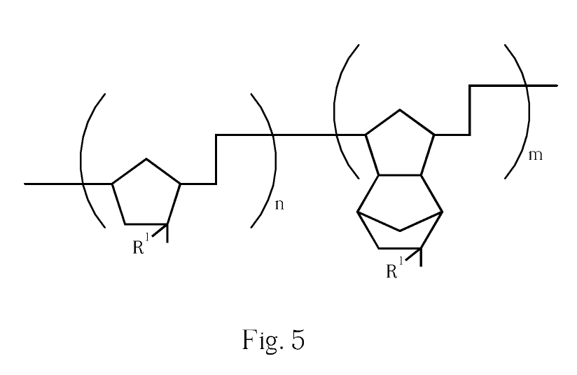

The protection layer 56 is penetrable by light of any wavelength, particularly by exposure light, so that the exposure light is not shielded. Generally, exposure light is UV light with a wavelength of 248 nm, 193 nm, or 157 nm, EUV light, or X-rays. The light transmittance for these types of exposure light is preferably larger than 90%, and the refraction rate of the protection layer 56 should be higher than the refraction rate of air. The material of the protection layer 56 can be any suitable transparent material that allows the exposure light to pass. The material of the protection layer 56 can be an organic material, an inorganic material, a polymer, a copolymer, a hybrid polymer, or any combination of the aforementioned materials. In this embodiment, the material of the protection layer 56 is ring opening metathesis polymer (ROMP). Please refer to FIG. 5. FIG. 5 illustrates the chemical structure of ring opening metathesis polymer (ROMP). Since ROMP is penetrable by light of any wavelength, the exposure light is not shielded.

It is to be noted that the material of the protection layer 56 can also be cyclo-olefin, methacrylate, or other suitable materials. In addition, the glass transition temperature of the protection layer 56 is preferably larger than 90 degree Celsius so that the protection layer 56 can remain stable during the exposure process. For the same reason, the molecular weight of the protection layer 56 is preferably larger than 3000 if a polymer is adopted. The protection layer 56 can also be a conductive material so as to provide electrostatic discharge protection. In addition, in this embodiment the protection layer 56 has a smooth surface, and can be formed by depositing techniques, coating techniques, or any suitable thin-film techniques.

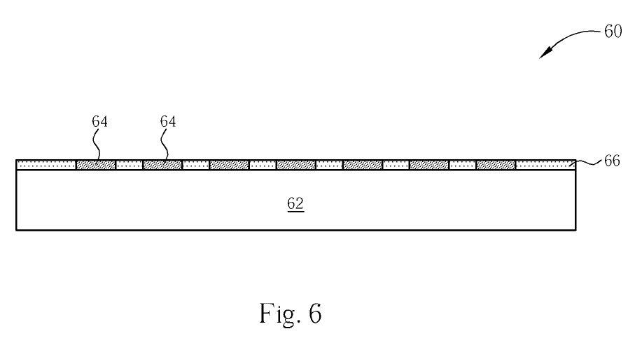

Please refer to FIG. 6. FIG. 6 illustrates a schematic view of a reticle 60 according a second preferred embodiment of the present invention. As shown in FIG. 6, the reticle 60 of the present invention includes a reticle body 62, a pattern 64 disposed on a first surface of the reticle body 62, and a protection layer 66 disposed on the first surface of the reticle body 62. In contrast with the first preferred embodiment, the protection layer 66 in this embodiment only covers the first surface of the reticle body 62.

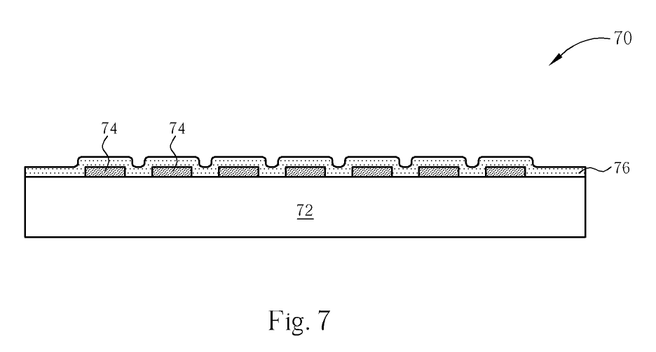

Please refer to FIG. 7. FIG. 7 illustrates a schematic view of a reticle 70 according a third preferred embodiment of the present invention. As shown in FIG. 7, the reticle 70 of the present invention includes a reticle body 72, a pattern 74 disposed on a first surface of the reticle body 72, and a protection layer 76 disposed on the first surface of the reticle body 72. In this embodiment, the protection layer 76 covers both the first surface of the reticle body 72 and the pattern 74, but the protection layer 76 has a bumpy surface.

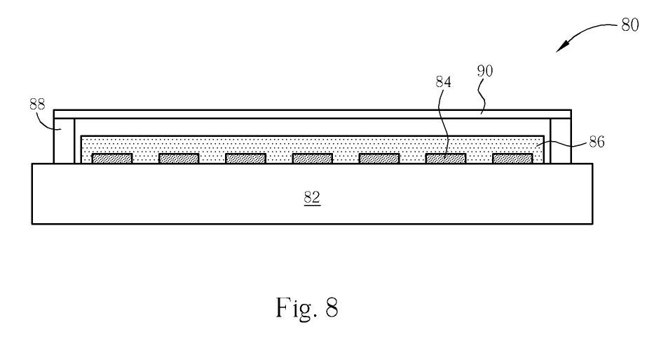

Please refer to FIG. 8. FIG. 8 illustrates a schematic view of a reticle 80 according a fourth preferred embodiment of the present invention. As shown in FIG. 8, the reticle 80 of the present invention includes a reticle body 82, a pattern 84 disposed on a first surface of the reticle body 82, and a protection layer 86 disposed on the first surface of the reticle body 82. In this embodiment, the reticle 80 further includes a frame 88 mounted on the reticle body 82, and a pellicle 90 mounted on the frame 88. In this embodiment, the reticle 80 includes both the protection layer 86 and the pellicle 90, and the protection layer 86 can have any form disclosed in the aforementioned embodiments.

By virtue of the protection layer being directly disposed on the reticle body, exposure light shielded by the haze defect will no longer focus on the photoresist layer. Consequently, the accuracy of pattern transfer is ensured.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A reticle comprising:
a reticle body having a first surface;
a pattern disposed on the first surface of the reticle body; and
at least a protection layer with highly transparency for any wavelength of exposure light disposed on the first surface of the reticle body, the protection layer covering the first surface of the reticle body, and the protection layer having a refraction rate higher than that of air.

2. The reticle of claim 1, wherein the protection layer further covers the pattern and isolates the pattern from the environment.

3. The reticle of claim 1, further comprising a frame mounted on the reticle body, and a pellicle mounted on the frame.

4. The reticle of claim 1, wherein the protection layer has a light transmittance larger than 90%.

5. The reticle of claim 1, wherein the glass transition temperature of the protection layer is larger than 90 degrees C.

6. The reticle of claim 1, wherein the molecular weight of the protection layer is larger than 3000.

7. The reticle of claim 1, wherein the protection layer is a polymer.

8. The reticle of claim 7, wherein the protection layer is a hybrid polymer or a copolymer.

9. The reticle of claim 1, wherein the protection layer is selected from a group of materials consisting of cyclo-olefin, ring opening metathesis polymer (ROMP), and methacrylate.

10. The reticle of claim 1, wherein the protection layer is a conductive material, and the protection layer further provides electrostatic discharge protection.

11. The reticle of claim 1, wherein the protection layer is formed by coating techniques or by depositing techniques.

12. A reticle comprising:
a reticle body having a first surface;
a pattern disposed on the first surface of the reticle body;
at least a protection layer with highly transparency for any wavelength of exposure light disposed on the first surface of the reticle body, the protection layer being in contact with the pattern and the first surface of the reticle body, and the protection layer having a refraction rate higher than that of air;
a frame mounted on the reticle body; and
a pellicle positioned over the protection layer.

13. The reticle of claim 12, wherein the protection layer has a light transmittance larger than 90%.

14. The reticle of claim 12, wherein the glass transition temperature of the protection layer is larger than 90 degrees C.

15. The reticle of claim 12, wherein the molecular weight of the protection layer is larger than 3000.

16. The reticle of claim 12, wherein the protection layer is a polymer.

17. The reticle of claim 16, wherein the protection layer is a hybrid polymer or a copolymer.

18. The reticle of claim 12, wherein the protection layer is selected from a group of materials consisting of cyclo-olefin, ring opening metathesis polymer (ROMP), and methacrylate.

19. The reticle of claim 12, wherein the protection layer is a conductive material, and the protection layer further provides electrostatic discharge protection.

20. The reticle of claim 12, wherein the protection layer is formed by coating techniques or depositing techniques.
